(19) United States
(12) Patent Application Publication
(10) Pub. No.: US 2021/0118773 A1
(43) Pub. Date: Apr. 22, 2021

(54) DEVICE SUBSTRATE AND COLLECTIVE SUBSTRATE

(71) Applicant: Murata Manufacturing Co., Ltd., Nagaokakyo-shi (JP)

(72) Inventor: Masakazu Fukumitsu, Nagaokakyo-shi (JP)

(21) Appl. No.: 17/135,101

(22) Filed: Dec. 28, 2020

Related U.S. Application Data
(63) Continuation of application No. PCT/JP2019/012433, filed on Mar. 25, 2019.

(30) Foreign Application Priority Data
Aug. 22, 2018 (JP) 2018-155758

(51) Int. Cl. H01L 23/48; H01L 21/768

(52) U.S. Cl. CPC H01L 23/481; H01L 21/76898

(57) ABSTRACT

A device substrate that includes a cleavable substrate having a cleavage direction, and a through electrode in the substrate. When a main surface of the substrate is viewed in a plan view thereof, a longitudinal direction of the through electrode is inclined with respect to the cleavage direction of the substrate. As a result, the longitudinal direction of the through electrode is not parallel to and does not match the cleavage direction of the substrate.

### CROSS REFERENCE TO RELATED APPLICATIONS

The present application is a continuation of International application No. PCT/JP2019/012433, filed Mar. 25, 2019, which claims priority to Japanese Patent Application No. 2018-155758, filed Aug. 22, 2018, the entire contents of each of which are incorporated herein by reference.

### FIELD OF THE INVENTION

The present invention relates to a device substrate and a collective substrate.

### BACKGROUND OF THE INVENTION

In the related art, as an example of a type of silicon wafer, a silicon wafer that has a (100) plane and a notch formed therein in a <110> or <100> orientation is known (see Patent Document 1). In such a silicon wafer, in the case where the notch is formed in the <110> orientation, the cleavage direction matches a direction perpendicular to the deepest portion of the notch, and in the case where the notch is formed in the <100> orientation, the cleavage direction matches a direction perpendicular to a linear portion of the notch.

Patent Document 1: Japanese Unexamined Patent Application Publication No. 2008-205354

### SUMMARY OF THE INVENTION

In a cleavable substrate such as a silicon wafer, cracks are likely to occur in the cleavage direction when mechanical stress or thermal stress is applied to the substrate. Thus, when a stress is applied to the notch in the silicon wafer described in Patent Document 1, there is a possibility that cracks may be formed starting from the notch, which in turn results in breakage of the wafer.

In addition, this type of wafer is used in a device, and typically, a through electrode is formed so as to extend through the wafer from one surface to the other surface of the wafer. Such a through electrode is formed in an oval shape or an elliptical shape when viewed in a plan view from a main surface of the substrate in order to increase its surface area. The mechanical strength of a polycrystalline through electrode is likely to be lower than that of a single-crystal wafer. When the main surface of the wafer is viewed in the plan view, if the longitudinal direction of a through electrode formed in the wafer and the cleavage direction of the wafer match each other, cracks are likely to be formed starting from the through electrode.

The present invention has been made in view of the above situation, and it is an object of the present invention to provide a device substrate and a collective substrate that are capable of suppressing formation of cracks starting from a through electrode.

A device substrate according to an aspect of the present invention includes a substrate that is cleavable and has a cleavage direction, and a through electrode in the substrate. A longitudinal direction of the through electrode is inclined with respect to the cleavage direction of the substrate when a main surface of the substrate is viewed in a plan view thereof.

A collective substrate according to another aspect of the present invention includes a plurality of the above-described device substrates.

According to the present invention, formation of cracks starting from a through electrode can be suppressed.

### BRIEF DESCRIPTION OF THE DRAWINGS

FIG. 1 is a plan view schematically illustrating a collective substrate according to an embodiment of the present invention.

FIG. 2 is a plan view schematically illustrating one of device substrates 10 according to an embodiment of the present invention.

FIG. 3 is a cross-sectional view illustrating a method of forming a through electrode illustrated in FIG. 1 and FIG. 2.

FIG. 4 is another cross-sectional view illustrating the method of forming the through electrode illustrated in FIG. 1 and FIG. 2.

FIG. 5 is another cross-sectional view illustrating the method of forming the through electrode illustrated in FIG. 1 and FIG. 2.

FIG. 6 is another cross-sectional view illustrating the method of forming the through electrode illustrated in FIG. 1 and FIG. 2.

### DETAILED DESCRIPTION OF THE PREFERRED EMBODIMENTS

An embodiment of the present invention will be described below. In the drawings that will be referred to in the following description, the same or similar components will be denoted by the same or similar reference signs. The drawings are examples and schematically illustrate the dimensions and shapes of the components, and the technical scope of the present invention should not be limited to the embodiment.

### Embodiment

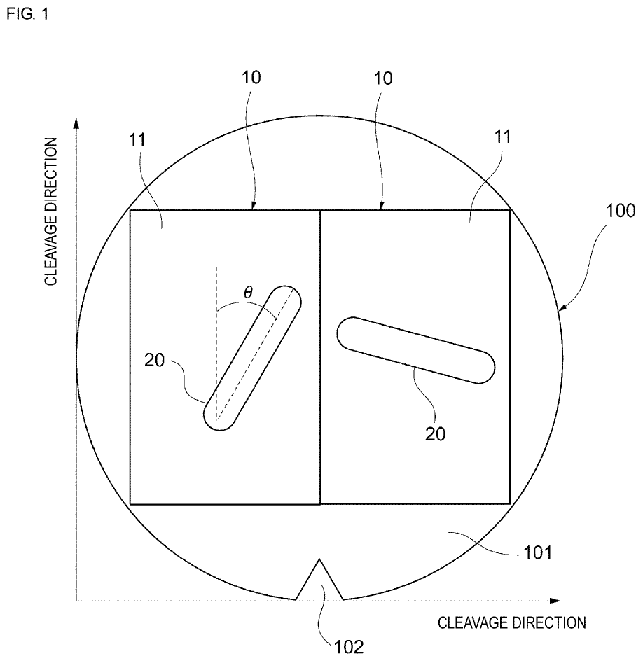

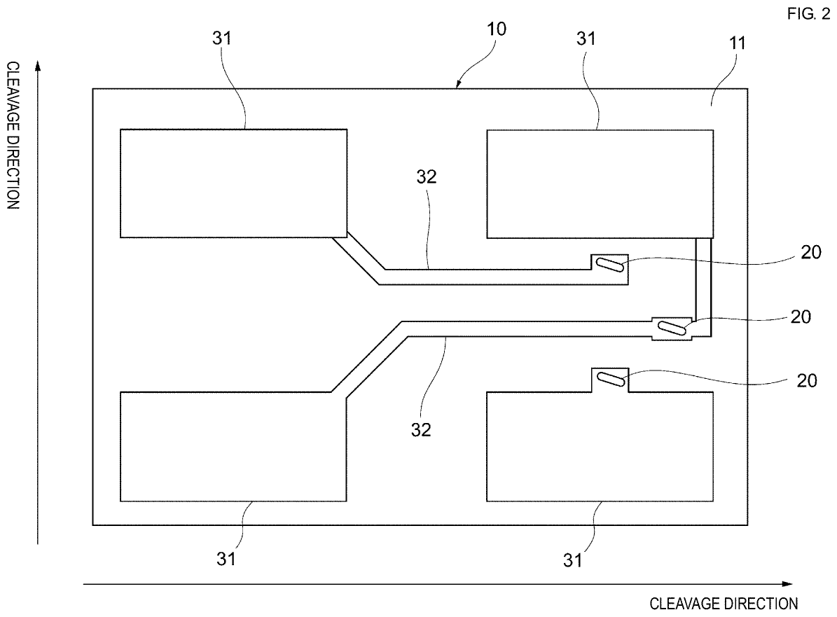

First, schematic configurations of a collective substrate 100 and the device substrates 10 according to embodiments of the present invention will be described with reference to FIG. 1 and FIG. 2. FIG. 1 is a plan view schematically illustrating the collective substrate 100 according to an embodiment of the present invention. FIG. 2 is a plan view schematically illustrating one of the device substrates 10 according to an embodiment of the present invention.

As illustrated in FIG. 1, the collective substrate 100 includes the two device substrates 10. For example, the collective substrate 100 is a flat plate made of a single-crystal silicon (Si). The collective substrate 100 has a main surface 101 having a crystal orientation of (100) and has a substantially circular shape when the main surface 101 is viewed in a plan view thereof. In addition, the collective substrate 100 has a notch 102 formed at a predetermined position. The notch 102 can be formed by cutting out a portion of the collective substrate 100 by a method such as machining. The notch 102 has a substantially circular shape when the main surface 101 is viewed in the plan view thereof.

After the plurality of device substrates 10 have been formed, the collective substrate 100 is cut with a dicing machine such that the device substrates 10 are cut out from the collective substrate 100 into chips.

Note that, although FIG. 1 illustrates the case where the collective substrate 100 includes the two device substrates 10, the present invention is not limited to this case. The collective substrate may include, for example, three or more device substrates as long as the collective substrate includes a plurality of device substrates.

Components of the device substrates 10 will be described below. Note that, in the following description, a surface of each of the device substrates 10 that is on the same plane as the main surface 101 of the collective substrate 100 will be referred to as a main surface (or a front surface), and another surface of each of the device substrates 10 that is opposite to the main surface of the device substrate 10 will be referred to as a rear surface.

Each of the device substrates 10 includes a substrate 11 and a through electrode 20 that are formed in the substrate 11.

Each of the substrates 11 can be obtained by a method of, for example, cutting the collective substrate 100 with a dicing machine. Accordingly, the substrate 11 has a property similar to that of the collective substrate 100. In other words, the substrate 11 is made of a single-crystal silicon (Si) and is cleavable. A direction in which the substrate 11 is cleavable (hereinafter simply referred to as “cleavage direction”) is parallel to the <110> orientation. The substrate 11 has a rectangular shape when a main surface of the substrate 11 is viewed in the plan view thereof (hereinafter simply referred to as “plan view”).

The through electrode 20 extends through the substrate 11 from the main surface of the substrate 11 to the rear surface (the surface opposite to the main surface) of the substrate 11. An electric conductor is formed into a film on the inner side of the through electrode 20 such that the interior of the through electrode 20 is filled with the electric conductor. The material of the electric conductor is, for example, polysilicon or a metal such as copper (Cu), nickel (Ni), or titanium tungsten (TiW).

As illustrated in FIG. 2, electrode pads 31 and connection wiring lines 32 are arranged on the main surface of the substrate 11, and a plurality of the through electrodes 20 are formed on the connection wiring lines 32. As a result, the through electrodes 20 enable the electrode pads 31 and the connection wiring lines 32, which are disposed on the main surface of the substrate 11, to be electrically connected to a circuit formed on the rear surface of the substrate 11.

The through electrodes 20 preferably have an oval shape in the plan view. Alternatively, the through electrode 20 may have an elliptical shape or a rectangular shape in the plan view. In the plan view, the longitudinal direction of the through electrode 20 is inclined with respect to the cleavage direction of the substrate 11.

More specifically, in the plan view, an angle θ that is formed by the longitudinal direction of the through electrode 20 and the cleavage direction of the substrate 11 is 1 degree to smaller than 45 degrees. Specifically, it is preferable that the angle θ be about 15 degrees.

In the present embodiment, although the case in which each of the device substrates 10 including the silicon substrate 11 has been described, the present invention is not limited to this case. The substrate included in each of the device substrates 10 may be made of a material other than silicon as long as the substrate is cleavable. However, it is preferable that the substrate included in each of the device substrates 10 be a silicon substrate, and in this case, a cleavable, single-crystal substrate can be easily obtained.

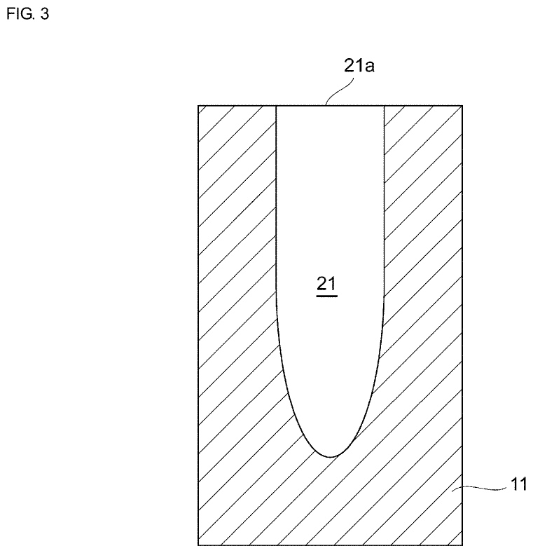

A method of forming the through electrode 20 will now be described with reference to FIG. 3 to FIG. 6. FIG. 3 to FIG. 6 are cross-sectional views illustrating the method of forming the through electrode 20 illustrated in FIG. 1 and FIG. 2.

First, a recess 21 is formed in the main surface of the substrate 11 (the collective substrate 100) as illustrated in FIG. 3. The recess 21 is formed by a method such as etching. An opening 21a of the recess 21 the same shape as the shape of the through electrode 20 in the plan view, which is an oval shape as illustrated in FIG. 1 and FIG. 2. Similar to the shape of the through electrode 20 in the plan view, which has been mentioned above, the opening 21a of the recess 21 may be an elliptical shape or a rectangular shape.

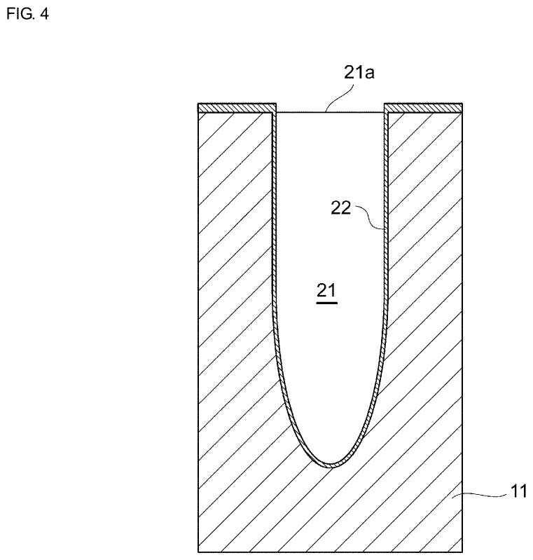

Next, as illustrated in FIG. 4, an insulating film 22 is formed so as to cover the periphery of the opening 21a and the inner side wall of the recess 21. The insulating film 22 is formed by a method such as spin coating, sputtering, or physical vapor deposition (PVD). The material of the insulating film 22 is, for example, a silicon dioxide (SiO₂).

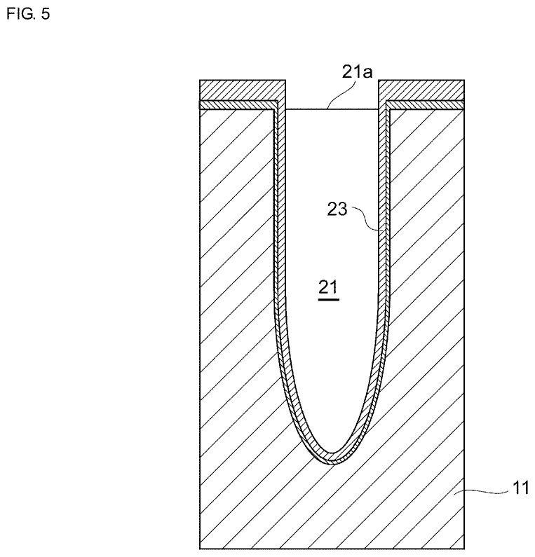

Subsequently, as illustrated in FIG. 5, an electric conductor 23 is formed into a film so as to cover the periphery of the opening 21a and the inner side wall of the recess 21. The electric conductor 23 is formed by a method such as spin coating, sputtering, or physical vapor deposition.

Here, only the film thickness of the electric conductor 23 that corresponds to half of the length of the opening 21a in the transverse direction of the opening 21a is required for the recess 21 whose opening 21a has an oval, elliptical, or a rectangular shape to be filled with the electric conductor 23. In contrast, the resistance of the through electrode 20 is inversely proportional to the surface area of the through electrode 20, and thus, the resistance of the through electrode 20 can be reduced by increasing the length of the opening 21a in the longitudinal direction of the opening 21a. Therefore, as a result of the through electrode 20 having an oval shape, an elliptical shape, or a rectangular shape in plan view, the amount of the electric conductor 23 can be reduced, and the resistance can be reduced.

The material of the electric conductor 23 is, for example, polysilicon. Accordingly, the thermal expansion coefficient of the electric conductor 23 is approximately the same as that of the substrate 11, and thus, a stress due to a difference in thermal expansion coefficient is less likely to be generated.

Alternatively, the material of the electric conductor 23 may be, for example, a metal such as copper (Cu), nickel (Ni), or titanium tungsten (TiW). In this case, the speed at which the electric conductor 23 is formed into a film in the recess 21 is relatively higher compared with the case where the material of the electric conductor 23 is polysilicon, and thus, the through electrode 20 can be easily formed.

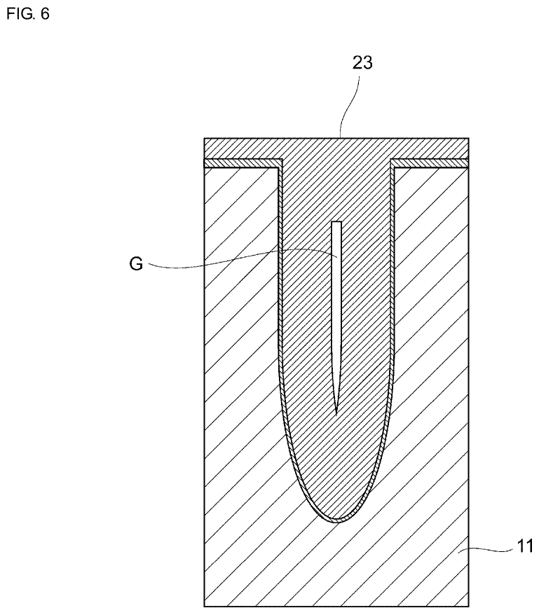

After that, as illustrated in FIG. 6, the recess 21 is filled with the electric conductor 23. Lastly, the substrate 11 (the collective substrate 100) is shaped by, for example, performing machining on the rear surface of the substrate 11 (the collective substrate 100) such that the recess 21 extends through the substrate 11 (the collective substrate 100). As a result, the through electrode 20 is formed in the substrate 11 (the collective substrate 100).

Since the minimum amount of the electric conductor 23 is supplied along the side wall of the recess 21, a gap G may sometimes be formed in a center portion of the electric conductor 23 as illustrated in FIG. 6. In the case where the gap G is formed in the electric conductor 23, the mechanical strength of the through electrode 20 deteriorates. Even in the case where the gap G is not formed in the electric conductor 23, since the electric conductor 23 is a polycrystalline body, the mechanical strength of the electric conductor 23 is likely to be relatively lower than that of the single-crystal substrate 11.

As described above, in each of the device substrates 10 according to the present description, the longitudinal direction of the through electrode 20 is inclined with respect to the cleavage direction of the substrate 11 in the plan view. Accordingly, the longitudinal direction of the through electrode 20 is not parallel to the cleavage direction of the substrate 11, that is, the longitudinal direction of the through electrode 20 does not match the cleavage direction. Thus, compared with the case where the longitudinal direction of the through electrode 20 matches the cleavage direction, the probability of formation of cracks can be reduced, and formation of cracks starting from the through electrode 20 can be suppressed.

In the present embodiment, although FIG. 1 illustrates the case where the longitudinal direction of the through electrode 20 of the device substrate 10 on the left-hand side is different from the longitudinal direction of the through electrode 20 of the device substrate 10 on the right-hand side, the present invention is not limited to this case. For example, the device substrates 10 included in the collective substrate 100 may include through electrodes having the same longitudinal direction in plan view. In addition, the number of the through electrodes 20 formed in each of the device substrates 10 is not limited to one as in the case illustrated in FIG. 1 and may be two or more as in the case illustrated in FIG. 2.

The exemplary embodiment of the present invention has been described above. In each of the device substrates 10 according to an embodiment of the present invention, the longitudinal direction of the through electrode 20 is inclined with respect to the cleavage direction of the substrate 11 when the main surface of the substrate 11 is viewed in the plan view thereof. Accordingly, the longitudinal direction of the through electrode 20 is not parallel to the cleavage direction of the substrate 11, that is, the longitudinal direction of the through electrode 20 does not match the cleavage direction. Thus, compared with the case where the longitudinal direction of the through electrode 20 matches the cleavage direction of the substrate, the probability of formation of cracks can be reduced, and formation of cracks starting from the through electrode 20 can be suppressed.

In each of the above-described device substrates 10, in the plan view, the angle θ formed by the longitudinal direction of the through electrode 20 and the cleavage direction of the substrate 11 is 1 degree to smaller than 45 degrees. As a result, the device substrates 10 each of which is capable of suppressing formation of cracks starting from the through electrode 20 can be easily formed.

In each of the above-described device substrates 10, in the plan view, the through electrode 20 has an oval shape, an elliptical shape, or a rectangular shape. Here, only the film thickness of the electric conductor that corresponds to half of the length of the opening 21a in the transverse direction is required for the recess 21 whose opening 21a has an oval, elliptical, or a rectangular shape to be filled with the electric conductor. In contrast, the resistance of the through electrode 20 is inversely proportional to the surface area of the through electrode 20, and thus, the resistance of the through electrode 20 can be reduced by increasing the length of the opening 21a in the longitudinal direction. Therefore, as a result of the through electrode 20 having an oval shape, an elliptical shape, or a rectangular shape in the plan view, the amount of the electric conductor 23 can be reduced, and the resistance can be reduced.

In each of the above-described device substrates 10, the substrate is the substrate 11. As a result, a cleavable, single-crystal substrate can be easily obtained.

In each of the above-described device substrates 10, the material of the electric conductor 23 is polysilicon. Accordingly, the thermal expansion coefficient of the electric conductor 23 is approximately the same as that of the substrate 11, and thus, a stress due to a difference in thermal expansion coefficient is less likely to be generated. Therefore, formation of cracks starting from the through electrode 20 can be further suppressed.

In each of the above-described device substrates 10, the material of the electric conductor 23 is a metal. As a result, the speed at which the electric conductor 23 is formed into a film in the recess 21 is relatively higher compared with the case where the material of the electric conductor 23 is polysilicon, and thus, each of the through electrodes 20 can be easily formed.

The collective substrate 100 according to the embodiment of the present invention includes the plurality of device substrate 10, which have been described above. As a result, the plurality of device substrates 10 each of which suppresses formation of cracks starting from the through electrode 20 can be manufactured at the same time.

Note that an embodiment has been described above for ease of understanding of the present invention and is not intended to limit the scope of the present invention. Changes and improvements may be made to the present invention within the scope of the present invention, and the present invention includes equivalents thereof. In other words, design changes may be suitably made to the embodiment by those skilled in the art, and such embodiments are also within the scope of the present invention as long as they have the features of the present invention. For example, the elements included in the embodiment and the arrangements, materials, conditions, shapes, sizes and so forth of the elements are not limited to those described above as examples, and they may be suitably changed. In addition, the embodiment is an example. It is obvious that the configurations according to different embodiments may be partially replaced with each other or may be combined with each other, and embodiments obtained as a result of such replacements and combinations are also within the scope of the present invention as long as they have the features of the present invention.

### REFERENCE SIGNS LIST

10 device substrate
11 substrate
20 through electrode
21 recess
21a opening
22 insulating film
23 electric conductor
31 electrode pad
32 connection wiring line
100 collective substrate
101 main surface
102 notch
θ angle

1. A device substrate comprising:
a substrate that is cleavable and has a cleavage direction; and
a through electrode in the substrate,
wherein a longitudinal direction of the through electrode is inclined with respect to the cleavage direction of the substrate when a main surface of the substrate is viewed in a plan view thereof.

2. The device substrate according to claim 1, wherein, in the plan view, an angle between the longitudinal direction of the through electrode and the cleavage direction of the substrate is 1 degree to smaller than 45 degrees.

3. The device substrate according to claim 2, wherein the angle between the longitudinal direction of the through electrode and the cleavage direction of the substrate is 15 degrees.

4. The device substrate according to claim 1, wherein, in the plan view, the through electrode has an oval shape, an elliptical shape, or a rectangular shape.

5. The device substrate according to claim 1, wherein the substrate is a silicon substrate.

6. The device substrate according to claim 5, wherein the silicon substrate is a single-crystal silicon substrate.

7. The device substrate according to claim 1, wherein the through electrode comprises an electric conductor.

8. The device substrate according to claim 7, wherein a material of the electric conductor is polysilicon.

9. The device substrate according to claim 7, wherein a material of the electric conductor is a metal.

10. The device substrate according to claim 7, wherein, in the plan view, the through electrode has an oval shape, an elliptical shape, or a rectangular shape, and a film thickness of the electric conductor is half of a length of a transverse direction of the longitudinal direction of the through electrode.

11. The device substrate according to claim 1, wherein the through electrode comprises:
an insulating film covering a periphery of an opening of a recess of the through electrode and an inner side wall of the recess;
an electric conductor on the insulating film.

12. The device substrate according to claim 11, wherein a material of the electric conductor is polysilicon.

13. The device substrate according to claim 11, wherein a material of the electric conductor is a metal.

14. The device substrate according to claim 11, wherein, in the plan view, the through electrode has an oval shape, an elliptical shape, or a rectangular shape, and a film thickness of the electric conductor is half of a length of a transverse direction of the longitudinal direction of the through electrode.

15. A collective substrate comprising:
a plurality of the device substrates according to claim 1.
